(19) United States
(12) Patent Application Publication
(10) Pub. No.: US 2026/0020329 A1
(43) Pub. Date: Jan. 15, 2026

(54) SEMICONDUCTOR DEVICE, ELECTRONIC SYSTEM INCLUDING THE SAME, AND METHOD FOR MANUFACTURING THE SEMICONDUCTOR DEVICE

(71) Applicant: SAMSUNG ELECTRONICS CO., LTD., SUWON-SI (KR)

(72) Inventors: Yong Min JO, Suwon-si (KR); Ryoong Bin LEE, Suwon-si (KR); Ki Ryung NAM, Suwon-si (KR); Nak Jin SON, Suwon-si (KR); Soo Eun SHIN, Suwon-si (KR); Sang Cheol YANG, Suwon-si (KR); Dae Seung WIE, Suwon-si (KR); Jun Yong HWANG, Suwon-si (KR)

(21) Appl. No.: 19/212,931

(22) Filed: May 20, 2025

(30) Foreign Application Priority Data
Jul. 12, 2024 (KR) 10-2024-0092346

(51) Int. Cl. H10D 84/83

(52) U.S. Cl. CPC H10D 84/8314

(57) ABSTRACT

The semiconductor device includes a substrate including a first area having a first surface and a second area having a second surface, wherein a vertical level of the first surface is different from a vertical level of the second surface; a first gate structure disposed on the first area, wherein the first gate structure includes a first gate insulating film and a first gate electrode layer disposed on the first gate insulating film; a second gate structure disposed on the second area, wherein the second gate structure includes a second gate insulating film, and a second gate electrode layer disposed on the second gate insulating film, wherein the second gate electrode layer includes first and second polysilicon layers on the second gate insulating film, wherein the first polysilicon layer is disposed between the first surface and the second surface, and the second polysilicon layer is disposed higher the first surface.

### CROSS-REFERENCE TO RELATED APPLICATION

This application claims priority under 35 USC § 119 to Korean Patent Application No. 10-2024-0092346 filed on Jul. 12, 2024 in the Korean Intellectual Property Office, the disclosure of which is incorporated by reference herein in its entirety.

### TECHNICAL FIELD

The present inventive concept relates to a semiconductor device, an electronic system including the same, and a method for manufacturing the semiconductor device.

### DISCUSSION OF THE RELATED ART

As an electronic product becomes lighter, thinner, and simpler, the demand for high integration of a semiconductor device increases. As the semiconductor device become more highly integrated, sizes of components included in the semiconductor device, such as a transistor, further decrease, thereby possibly causing leakage current. Therefore, there is a desire to control the leakage current of the semiconductor device to increase performance and reliability of the semiconductor device.

In an electronic system that includes data storage, a semiconductor device that may store high-capacity data therein is desirable. Accordingly, a scheme to increase the data storage capacity of the semiconductor device is being studied. For example, in one approach to increase the data storage capacity of the semiconductor device, a semiconductor device including three-dimensionally arranged memory cells instead of two-dimensionally arranged memory cells has been under development.

### SUMMARY

According to embodiments of the present inventive concept, a semiconductor device includes: a substrate including a first area and a second area, wherein the first area has a first surface, and the second area has a second surface, wherein a vertical level of the first surface is different from a vertical level of the second surface; a first gate structure disposed on the first surface of the first area, wherein the first gate structure includes a first gate insulating film and a first gate electrode layer that is disposed on the first gate insulating film; a second gate structure disposed on the second surface of the second area, wherein the second gate structure includes a second gate insulating film and a second gate electrode layer, wherein the second gate insulating film includes a material having a dielectric constant that is lower than a dielectric constant of the first gate insulating film, and the second gate electrode layer is disposed on the second gate insulating film; and an element isolation film disposed in the substrate and between the first and second gate structures, wherein the second gate electrode layer includes first and second polysilicon layers sequentially stacked on the second gate insulating film and including different materials from each other, wherein the first polysilicon layer is disposed between the first surface and the second surface, and the second polysilicon layer is disposed at a vertical level that is above the vertical level of the first surface.

According to embodiments of the present inventive concept, a semiconductor device includes: a cell area; and a peripheral circuit area electrically connected to the cell area, wherein the cell area includes: a plurality of gate electrodes stacked and spaced apart from each other in a first direction; and a channel structure extending through the plurality of gate electrodes in the first direction, wherein the peripheral circuit area includes: a substrate including different first to third areas; a first peripheral transistor disposed on the first area and including a first gate insulating film and a first gate electrode layer, wherein the first gate insulating film includes a material having a dielectric constant that is higher than a dielectric constant of silicon oxide, and the first gate electrode layer is disposed on the first gate insulating film; a second peripheral transistor disposed on the second area and including a second gate insulating film and a second gate electrode layer, wherein the second gate insulating film includes a material having a dielectric constant that is higher than a dielectric constant of silicon oxide, and the second gate electrode layer is disposed on the second gate insulating film; and a third peripheral transistor disposed on the third area and including a third gate insulating film, a first polysilicon layer, and a second polysilicon layer, wherein the third gate insulating film includes a material having a dielectric constant that is different from a dielectric constant of each of the first and second gate insulating films, wherein the first polysilicon layer is disposed on the third gate insulating film, and the second polysilicon layer is disposed on the first polysilicon layer, wherein a carbon content of the first polysilicon layer and a carbon content of the second polysilicon layer are different from each other, wherein the first peripheral transistor and the third peripheral transistor are positioned at different vertical levels from each other, and the second peripheral transistor and the third peripheral transistor are positioned at different vertical levels from each other, wherein a first distance in the vertical direction between the first peripheral transistor and the third peripheral transistor is smaller than a second distance in the vertical direction between the second peripheral transistor and the third peripheral transistor.

According to embodiments of the present inventive concept, an electronic system includes: a main substrate; a semiconductor device disposed on the main substrate and including a cell area and a peripheral circuit area; and a controller disposed on the main substrate and electrically connected to the semiconductor device, wherein the semiconductor device includes: a first substrate disposed on the cell area; a plurality of word lines stacked on the first substrate and spaced apart from each other; a channel structure extending in a vertical direction intersecting with an upper surface of the first substrate to extend through the plurality of word lines; a bit line disposed on the plurality of word lines and connected to the channel structure; a second substrate disposed on the peripheral circuit area and including different first to third areas; and a peripheral circuit element disposed on the second substrate, wherein the peripheral circuit element includes: a first peripheral transistor disposed on the first area and including a first gate insulating film, which includes a material having a dielectric constant that is higher than a dielectric constant of silicon oxide, and a first gate electrode layer, which is disposed on the first gate insulating film; a second peripheral transistor disposed on the second area and including a second gate insulating film, which includes a material having a dielectric constant that is higher than a dielectric constant of silicon oxide, and a second gate electrode layer, which is disposed on the second gate insulating film; and a third peripheral transistor disposed on the third area and including a third gate insulating film, which includes a material having a dielectric constant that is different from a dielectric constant of each of the first and second gate insulating films, a first polysilicon layer, which is disposed on the third gate insulating film, and a second polysilicon layer, which is disposed on the first polysilicon layer, wherein the first polysilicon layer and the second polysilicon layer include different materials from each other, wherein the second substrate has a first upper surface, which has a first vertical level in the first and second areas, and a second upper surface, which has a second vertical level in the third area, wherein the first vertical level and the second vertical level are different from each other, wherein a vertical level of the first polysilicon layer is positioned between the first vertical level and the second vertical level, and the second polysilicon layer is positioned at the first vertical level.

### BRIEF DESCRIPTION OF DRAWINGS

The above and other aspects and features of the present inventive concept will become more apparent by describing in detail embodiments thereof with reference to the attached drawings, in which:

FIG. 1 is a layout diagram for illustrating a semiconductor device according to embodiments of the present inventive concept;

FIG. 2 is a schematic cross-sectional view taken along lines A-A, B-B, and C-C of FIG. 1;

FIGS. 3, 4, 5, 6, 7, 8, 9, 10, 11, 12 and 13 are diagrams of intermediate structures corresponding to intermediate steps of a method for manufacturing a semiconductor device according to embodiments of the present inventive concept;

FIG. 14 is a schematic plan view for illustrating a semiconductor device according to embodiments of the present inventive concept;

FIG. 15 is a block diagram for illustrating the semiconductor device of FIG. 14;

FIG. 16 is a schematic cross-sectional view for illustrating a semiconductor device according to embodiments of the present inventive concept;

FIG. 17 is an enlarged view of an area R3 of FIG. 16;

FIG. 18 is an example block diagram for illustrating an electronic system according to embodiments of the present inventive concept;

FIG. 19 is an example perspective view for illustrating an electronic system according to embodiments of the present inventive concept; and

FIG. 20 is a schematic cross-sectional view taken along a line I-I of FIG. 19.

### DETAILED DESCRIPTIONS

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the spirit and scope of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, in the example, terms “below” and “beneath” may encompass both an orientation of above, below and beneath. The device may be otherwise oriented (e.g., rotated 90 degrees or at other orientations) and the spatially relative descriptors used herein may be interpreted accordingly.

Embodiments of the present inventive concept relate to a semiconductor device with increased reliability, performance, and data storage capacity. Embodiments of the present invention may include a three-dimensional arrangement of memory cells to overcome limitations of two-dimensional configurations, thereby enabling higher data storage within a compact structure.

According to embodiments of the present inventive concept, the semiconductor device may include a substrate with regions at different vertical levels, accommodating specialized gate structures with specific functions. These gate structures may include high-dielectric constant films and multi-layered polysilicon, which may reduce leakage currents and improve overall efficiency. The integration of high-and low-voltage transistors within the peripheral circuits allows the device to support diverse operations, such as memory management and communication with external controllers.

To ensure manufacturing precision, the method of manufacturing the semiconductor device may incorporate techniques that utilize protective polysilicon layers and material layering. For example, these processes may mitigate potential damage during fabrication, thereby increasing device reliability and production yield. The detailed design of the semiconductor device may support high-speed operations and increased thermal stability.

Embodiments of the present inventive concept may be incorporated into electronic systems, including data storage solutions like NAND flash memory and solid-state drives (SSD).

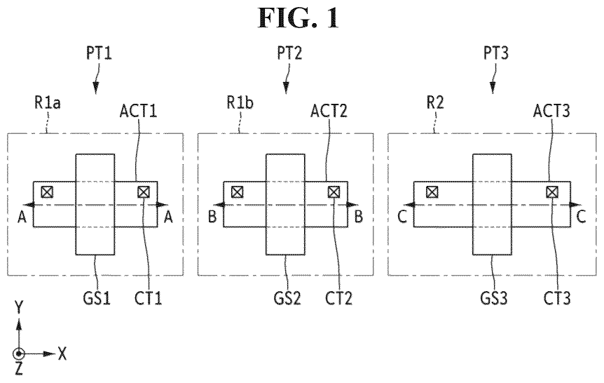

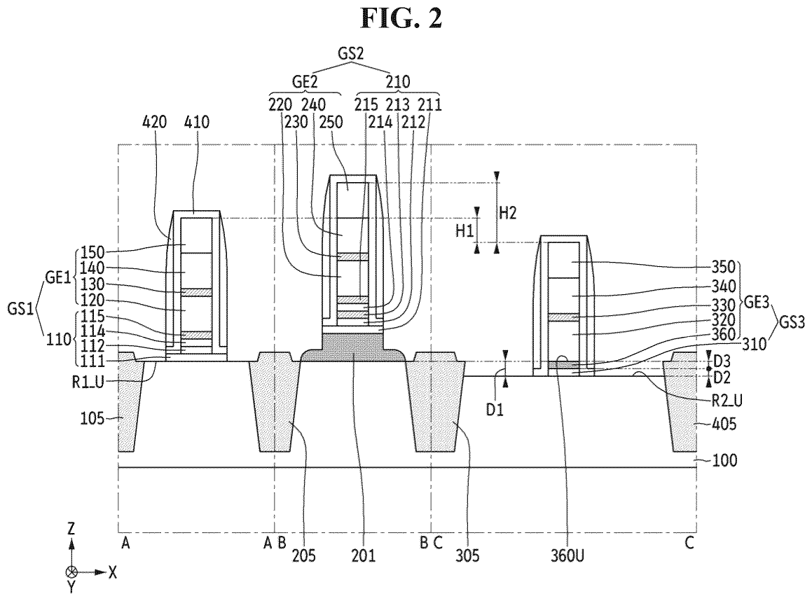

FIG. 1 is a layout diagram for illustrating a semiconductor device according to embodiments of the present inventive concept. FIG. 2 is a schematic cross-sectional view taken along lines A-A, B-B, and C-C in FIG. 1.

Referring to FIG. 1 and FIG. 2, the semiconductor device according to embodiments of the present inventive concept may include a substrate 100, a plurality of circuit elements PT1, PT2, and PT3, a plurality of element isolation films 105, 205, 305, and 405, a first spacer layer 410, and a second spacer layer 420.

The substrate 100 may extend in each of first and second directions X and Y that intersect each other. For example, the first and second directions X and Y may intersect each other to be perpendicular to each other. In embodiments of the present inventive concept, a third direction Z may be a direction that intersects each of the first and second directions X and Y perpendicularly. The third direction Z may mean a height direction perpendicular to each of a first surface R1_U and a second surface R2_U of the substrate 100 as described below.

The substrate 100 may include, for example, a semiconductor substrate such as a silicon substrate, a germanium substrate, or a silicon-germanium substrate. In addition, the substrate 100 may include a Silicon-On-Insulator (SOI) substrate or a Germanium-On-Insulator (GOI) substrate.

The substrate 100 may include different first to third areas R1a, R1b, and R2. For example, a voltage applied to the third area R2 may be greater than a voltage applied to each of the first area R1a and the second area R1b.

The substrate 100 may have the first surface R1_U in the first area R1a and the second area R1b. The substrate 100 may have the second surface R2_U in the third area R2. In embodiments of the present inventive concept, each of the first surface R1_U and the second surface R2_U may mean one surface of the substrate 100 on which the plurality of circuit elements PT1, PT2, and PT3 are formed. The first surface R1_U and the second surface R2_U may be positioned at different vertical levels from each other. Based on the third direction Z, the second surface R2_U may be positioned at a lower vertical level than a vertical level of the first surface R1_U.

A first active area ACT1 may be formed on the first area R1a. A second active area ACT2 may be formed on the second area R1b. A third active area ACT3 may be formed on the third area R2.

The plurality of circuit elements PT1, PT2 and PT3 may be formed on the substrate 100. For example, the plurality of circuit elements PT1, PT2 and PT3 may be formed on the active area ACT1, ACT2, and ACT3 of the substrate 100.

Hereinafter, an example in which each of the plurality of circuit elements PT1, PT2 and PT3 is embodied as a transistor is described. However, this is only an example, and the technical idea of the present inventive concept is not limited thereto. For example, the plurality of circuit elements PT1, PT2 and PT3 may include various active elements such as transistors, as well as various passive elements such as capacitors, resistors, and inductors.

In embodiments of the present inventive concept, each of the plurality of circuit elements PT1, PT2 and PT3 may be a high voltage transistor or a low voltage transistor. In FIG. 1, the plurality of circuit elements PT1, PT2, and PT3 are depicted as being sequentially arranged in the first direction X. However, this is merely an example, and a position relationship of the plurality of circuit elements PT1, PT2, and PT3 in a plan view is not limited to what is depicted in the figures.

The first gate structure GS1 may be formed on the first area R1a of the substrate 100. The first gate structure GS1 may be formed on the first active area ACT1 of the substrate 100. In FIG. 1, the first gate structure GS1 is shown as extending in the second direction Y. However, this is only an example. The technical idea of the present inventive concept is not limited thereto. For example, the first gate structure GS1 may extend in a direction different from the second direction Y.

The first gate structure GS1 may include a conductive material. In embodiments of the present inventive concept, the first gate structure GS1 may include a plurality of conductive films. The plurality of conductive films may include, for example, at least one of polysilicon or a metal material. A structure and a material of the first gate structure GS1 are described later.

The second gate structure GS2 may be formed on the second area R1b of the substrate 100. The second gate structure GS2 may be formed on the second active area ACT2 of the substrate 100. In FIG. 1, the second gate structure GS2 is shown extending in the second direction Y. However, this is only an example. The technical idea of the present inventive concept is not limited thereto. For example, the second gate structure GS2 may extend in a direction different from the second direction Y.

The second gate structure GS2 may include a conductive material. In embodiments of the present inventive concept, the second gate structure GS2 may include a plurality of conductive films. The plurality of conductive films may include, for example, at least one of polysilicon or a metal material. A structure and a material of the second gate structure GS2 are described later.

The third gate structure GS3 may be formed on the third area R2 of the substrate 100. The third gate structure GS3 may be formed on the third active area ACT3 of the substrate 100. In FIG. 1, the third gate structure GS3 is shown extending in the second direction Y. However, this is only an example. The technical idea of the present inventive concept is not limited thereto. For example, the third gate structure GS3 may extend in a direction different from the second direction Y.

The third gate structure GS3 may include a conductive material. In embodiments of the present inventive concept, the third gate structure GS3 may include a plurality of conductive films. The plurality of conductive films may include, for example, at least one of polysilicon or a metal material. A structure and a material of the third gate structure GS3 are described later.

The first active area ACT1 may be formed in the substrate 100 and extend between both opposing sides of the first circuit element PT1. The first active area ACT1 may extend in the first direction X intersecting the second direction Y. The first active arca ACT1 may be doped with an impurity. For example, when the first circuit element PT1 is an n-type (or p-type) transistor, the first active area ACT1 may be doped with a p-type (or n-type) impurity. In embodiments of the present inventive concept, the first circuit element PT1 may be an NMOS transistor.

A first contact CT1 may be formed on the first active area ACT1. The first contact CT1 may be connected to an impurity doped area of the substrate 100. First contacts CT1 may be respectively disposed on two opposing sides of the first gate structure GS1.

The second active arca ACT2 may be formed in the substrate 100 and may extend between both opposing sides of the second circuit element PT2. The second active arca ACT2 may extend in the first direction X intersecting the second direction Y. The second active arca ACT2 may be doped with an impurity. For example, when the second circuit element PT2 is an n-type (or p-type) transistor, the second active area ACT2 may be doped with a p-type (or n-type) impurity. In embodiments of the present inventive concept, the second circuit element PT2 may be a PMOS transistor.

A second contact CT2 may be formed on the second active area ACT2. The second contact CT2 may be connected to an impurity doped area of the substrate 100. Second contacts CT2 may be respectively disposed on two opposing sides of the second gate structure GS2. In an embodiment of the present inventive concept, the second contact CT2 may be disposed on a silicon germanium layer 201 as described below and connected to the silicon germanium layer 201.

The third active area ACT3 may be formed in the substrate 100 and may extend between both opposing sides of the third circuit element PT3. The third active area ACT3 may extend in the first direction X intersecting the second direction Y. The third active area ACT3 may be doped with an impurity. For example, when the third circuit element PT3 is an n-type (or p-type) transistor, the third active area 413 may be doped with a p-type (or n-type) impurity.

A third contact CT3 may be formed on the third active area ACT3. The third contact CT3 may be connected to the impurity doped area of the substrate 100. Third contacts CT3 may be respectively disposed on two opposing sides of the third gate structure GS3.

The first circuit element PT1 may be disposed on the first surface R1_U of the first area R1a. The first circuit element PT1 may include a first gate insulating film 110 and a first gate electrode layer GE1. The second circuit element PT2 may be disposed on the first surface R1_U of the second area R1b. The second circuit element PT2 may include a second gate insulating film 210 and a second gate electrode layer GE2. The third circuit element PT2 may be disposed on the second surface R2_U of the third area R2. The third circuit element PT3 may include a third gate insulating film 310 and a third gate electrode layer GE3.

In embodiments of the present inventive concept, each of the first circuit element PT1 and the second circuit element PT2 may be a low-voltage transistor. For example, a low voltage of about 5 V or lower may be applied to each of the first circuit element PT1 and the second circuit element PT2. However, the present inventive concept is not limited thereto.

In embodiments of the present inventive concept, the third circuit element PT3 may be a high-voltage transistor. For example, a high voltage of about 10 V to about 40 V may be applied to the third circuit element PT3. However, the present inventive concept is not limited thereto.

The first gate insulating film 110 may be disposed on the first surface R1_U of the first area R1a. The first gate electrode layer GE1 may be disposed on the first gate insulating film 110. In other words, the first gate insulating film 110 may be arranged between the first gate electrode layer GE1 and the substrate 100.

The first gate insulating film 110 may include a (1-1)-st gate dielectric film 111, a (1-1)-st high-dielectric constant dielectric film 112, a (1-2)-nd high-dielectric constant dielectric film 114, and a (1-2)-nd barrier film 115 that are sequentially stacked on the first surface R1_U. In an embodiment of the present inventive concept, a barrier film is not be interposed between the (1-1)-st high-dielectric constant dielectric film 112 and the (1-2)-nd high-dielectric constant dielectric film 114.

The (1-1)-st gate dielectric film 111 may include an oxide. For example, the (1-1)-st gate dielectric film 111 may include a silicon oxide. However, the present inventive concept is not limited thereto.

The (1-1)-st high dielectric constant dielectric film 112 may include a high dielectric constant material. The high dielectric constant material may refer to a dielectric material having a dielectric constant that is higher than that of silicon oxide (SiO₂). The high dielectric constant material may include, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and/or praseodymium oxide (Pr₂O₃). In some embodiments of the present inventive concept, the (1-1)-st high dielectric constant dielectric film 112 may include hafnium oxide (HfO₂).

The (1-2)-nd high dielectric constant dielectric film 114 may include a high dielectric constant material. The high dielectric constant material may mean a dielectric material having a dielectric constant that is higher than that of silicon oxide (SiO₂). The high dielectric constant material may include, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and/or praseodymium oxide (Pr₂O₃). In embodiments of the present inventive concept, the (1-2)-nd high-dielectric constant dielectric film 114 may include lanthanum oxide (La₂O₃).

The (1-2)-nd barrier film 115 may include a metal material. For example, the (1-2)-nd barrier film 115 may include at least one of titanium (Ti), titanium nitride (TiN), tantalum (Ta), and/or tantalum nitride (TaN).

The first gate electrode layer GE1 may include a (1-1)-st gate electrode layer 120, a (1-3)-rd barrier film 130, a (1-2)-nd gate electrode layer 140, and a first capping layer 150 that are sequentially stacked on the (1-2)-nd barrier film 115.

The (1-1)-st gate electrode layer 120 may include, for example, polysilicon.

The (1-3)-rd barrier film 130 may include a metal material. For example, the (1-3)-rd barrier film 130 may include at least one of titanium (Ti), titanium nitride (TiN), tantalum (Ta), and/or tantalum nitride (TaN).

The (1-2)-nd gate electrode layer 140 may include at least one of, for example, tungsten (W), tungsten nitride (WN), ruthenium (Ru), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), and/or vanadium (V).

The first capping layer 150 may include, for example, silicon nitride (SiN).

The second gate insulating film 210 may be disposed on the silicon germanium layer 201. In other words, the silicon germanium layer 201 may be disposed between the second gate insulating film 210 and the substrate 100.

The second gate insulating film 210 may be disposed on the first surface R1_U of the second area R1b. The second gate electrode layer GE2 may be disposed on the second gate insulating film 210. In other words, the second gate insulating film 210 may be disposed between the second gate electrode layer GE2 and the substrate 100. For example, the second gate insulating film 210 may be disposed between the second gate electrode layer GE2 and the silicon germanium layer 201.

The second gate insulating film 210 may include a (2-1)-st gate dielectric film 211, a (2-1)-st high-dielectric constant dielectric film 212, a (2-1)-st barrier film 213, a (2-2)-nd high-dielectric constant dielectric film 214, and a (2-2)-nd barrier film 115 that are sequentially stacked on the first surface R1_U.

The (2-1)-st gate dielectric film 211 may include an oxide. For example, the (2-1)-st gate dielectric film 211 may include silicon oxide. However, the present inventive concept is not limited thereto.

The (2-1)-st high dielectric constant dielectric film 212 may include a high dielectric constant material. The high dielectric constant material may mean a dielectric material having a dielectric constant that is higher than that of silicon oxide (SiO₂). The high dielectric constant material may include, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and/or praseodymium oxide (Pr₂O₃). In some embodiments), the (1-2)-nd high-dielectric constant dielectric film 114 may include lanthanum oxide (La₂O₃). In some embodiments, the (2-1)-st high-dielectric constant dielectric film 212 may include hafnium oxide (HfO₂).

The (2-1)-st barrier film 213 may include a metal material. For example, the (2-1)-st barrier film 213 may include at least one of titanium (Ti), titanium nitride (TiN), tantalum (Ta), and/or tantalum nitride (TaN).

The (2-2)-nd high dielectric constant dielectric film 214 may include a high dielectric constant material. The high dielectric constant material may mean a dielectric material having a dielectric constant that is higher than that of silicon oxide (SiO₂). The high dielectric constant material may include, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and/or praseodymium oxide (Pr₂O₃). In embodiments of the present inventive concept, the (1-2)-nd high-dielectric constant dielectric film 114 may include lanthanum oxide (La₂O₃). In embodiments of the present inventive concept, the (2-2)-nd high-dielectric constant dielectric film 214 may include lanthanum oxide (La₂O₃).

The (2-2)-nd barrier film 215 may include a metal material. For example, the (2-2)-nd barrier film 215 may include at least one of titanium (Ti), titanium nitride (TiN), tantalum (Ta), and/or tantalum nitride (TaN).

The second gate electrode layer GE2 may include a (2-1)-st gate electrode layer 220, a (2-3)-rd barrier film 230, a (2-2)-nd gate electrode layer 240, and a second capping layer 250 that are sequentially stacked on the (2-2)-nd barrier film 215.

The (2-1)-st gate electrode layer 220 may include, for example, polysilicon.

The (2-3)-rd barrier film 230 may include a metal material. For example, the (2-3)-rd barrier film 230 may include at least one of titanium (Ti), titanium nitride (TiN), tantalum (Ta), and/or tantalum nitride (TaN).

The (2-2)-nd gate electrode layer 240 may include at least one of, for example, tungsten (W), tungsten nitride (WN), ruthenium (Ru), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), and/or vanadium (V).

The second capping layer 250 may include, for example, silicon nitride (SiN).

The third gate insulating film 310 may be disposed on the second surface R2_U of the third area R2. The third gate electrode layer GE3 may be disposed on the third gate insulating film 310. In other words, the third gate insulating film 310 may be disposed between the third gate electrode layer GE3 and the substrate 100.

The third gate insulating film 310 may include at least one of, for example, silicon oxide, silicon nitride, silicon oxynitride, and a low-k material having a dielectric constant lower than that of silicon oxide. For example, the low-k material may include, but is not limited to, at least one of FOX (Flowable Oxide), TOSZ (Tonene SilaZene), USG (Undoped Silica Glass), BSG (Borosilica Glass), PSG (PhosphoSilica Glass), BPSG (BoroPhosphoSilica Glass), PETEOS (Plasma Enhanced Tetra Ethyl Ortho Silicate), FSG (Fluoride Silicate Glass), CDO (Carbon Doped silicon Oxide), Xerogel, Aerogel, Amorphous Fluorinated Carbon, OSG (Organo Silicate Glass), Parylene, BCB (bis-benzocyclobutenes), SiLK, polyimide, porous polymeric material, and combinations thereof.

The third gate electrode layer GE3 may include a first polysilicon layer 360, a (3-1)-st gate electrode layer 320, a (3-3)-rd barrier film 330, a (3-2)-nd gate electrode layer 340, and a third capping layer 350 that are sequentially stacked on the third gate insulating film 310.

The first polysilicon layer 360 may be disposed between the first surface R1_U and the second surface R2_U of the substrate 100. For example, the first polysilicon layer 360 may be at a level that is between a level of the first surface R1_U and a level of the second surface R2_U of the substrate 100.

The (3-1)-st gate electrode layer 320 may include, for example, polysilicon. In embodiments of the present inventive concept, the (3-1)-st gate electrode layer 320 may be referred to as a second polysilicon layer. The (3-1)-st gate electrode layer 320 may be disposed on the second surface R2_U.

The first polysilicon layer 360 and the (3-1)-st gate electrode layer 320 may include different materials from each other. For example, a carbon content in the first polysilicon layer 360 may be different from a carbon content in the (3-1)-st gate electrode layer 320.

The (3-3)-rd barrier film 330 may include a metal material. For example, the (3-3)-rd barrier film 330 may include at least one of titanium (Ti), titanium nitride (TiN), tantalum (Ta), and/or tantalum nitride (TaN).

The (3-2)-nd gate electrode layer 340 may include at least one of, for example, tungsten (W), tungsten nitride (WN), ruthenium (Ru), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), and/or vanadium (V).

The third capping layer 350 may include, for example, silicon nitride (SiN).

Specifically, referring to FIG. 2, in the third direction Z, a distance D1 between the first surface R1_U and the second surface R2_U may be equal to a sum of a thickness D2 of the third gate insulating film 310 and a thickness D3 of the first polysilicon layer 360. The distance D1 between the first surface R1_U and the second surface R2_U may be equal to the distance D1 between an upper surface 360U of the first polysilicon layer 360 and the second surface R2_U.

For example, the distance D1 between the first surface R1_U and the second surface R2_U may be about 720 Å. For example, the thickness D2 of the third gate insulating film 310 may be about 460 Å, and the thickness D3 of the first polysilicon layer 360 may be about 260 Å. However, the present inventive concept is not limited thereto.

In an embodiment of the present inventive concept, based on the third direction Z, the first gate insulating film 110, the second gate insulating film 210, and the third gate insulating film 310 might not be positioned at the same vertical level as one another. The third gate insulating film 310 may be positioned at a vertical level that is lower than that of each of the first and second gate insulating films 110 and 210. The first gate insulating film 110 may be positioned between the second gate insulating film 210 and the third gate insulating film 310. For example, the first gate insulating film 110 may be at a level that is between a level of the second gate insulating film 210 and a level of the third gate insulating film 310.

Based on the third direction Z, the first polysilicon layer 360 may be positioned at a vertical level that is lower than that of each of the first and second gate insulating films 110 and 210. The third gate structure GS3 may be positioned at a vertical level that is lower than that of each of the first and second gate structures GS1 and GS2.

Based on the third direction Z, the first gate electrode layer GE1 and the third gate electrode layer GE3 may be positioned at different vertical levels from each other. The second gate electrode layer GE2 and the third gate electrode layer GE3 may be positioned at different vertical levels from each other. The first circuit element PT1 and the third circuit element PT3 may be positioned at different vertical levels from each other, and the second circuit element PT2 and the third circuit element PT3 may be positioned at different vertical levels from each other.

Based on the third direction Z, a first distance H1 between an upper surface of the first gate electrode layer GE1 and an upper surface of the third gate electrode layer GE3 may be smaller than a second distance H2 between an upper surface of the second gate electrode layer GE2 and the upper surface of the third gate electrode layer GE3. The first distance H1 between the upper surface of the first circuit element PT1 and the upper surface of the third circuit element PT3 may be smaller than the second distance H2 between the upper surface of the second circuit element PT2 and the upper surface of the third circuit element PT3.

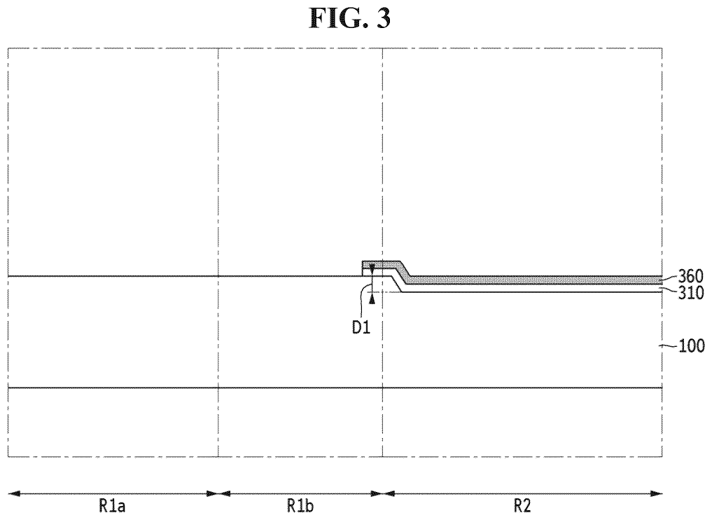

FIGS. 3 to 13 are diagrams of intermediate structures corresponding to intermediate steps of a method for manufacturing a semiconductor device according to embodiments of the present inventive concept. For convenience of descriptions, contents duplicate with those as described above using FIG. 1 and FIG. 2 are briefly described or the descriptions thereof are omitted.

Referring to FIG. 3, the substrate 100 including the first to third areas R1a, R1b, and R2 is provided. A recess having a first depth D1 may be formed in the substrate 100 of the third area R2. For example, the recess may be formed in the third area R2 of the substrate 100. The third gate insulating film 310 and the first polysilicon layer 360 may be sequentially formed within the recess of the substrate 100.

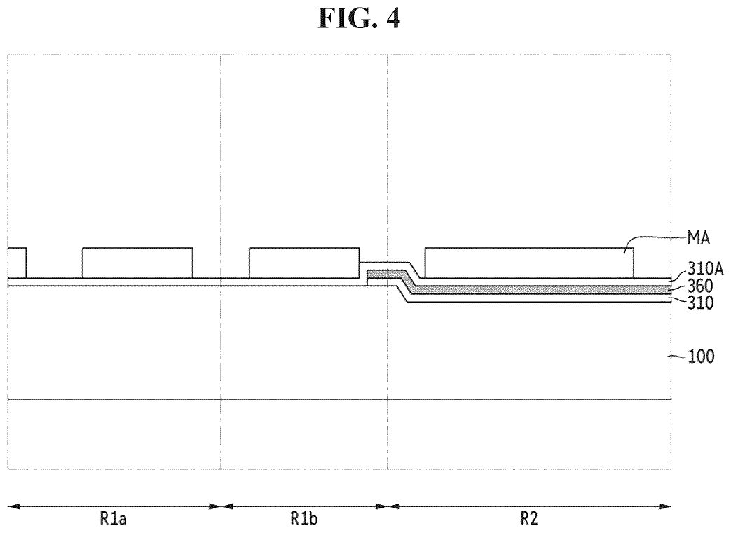

Referring to FIG. 4, an oxide film 310A may be formed on the substrate 100 and the first polysilicon layer 360 by using an atomic layer deposition process. The oxide film 310A may be formed in an atomic layer deposition process under a high temperature condition.

Thereafter, a mask pattern MA may be formed on the oxide film 310A.

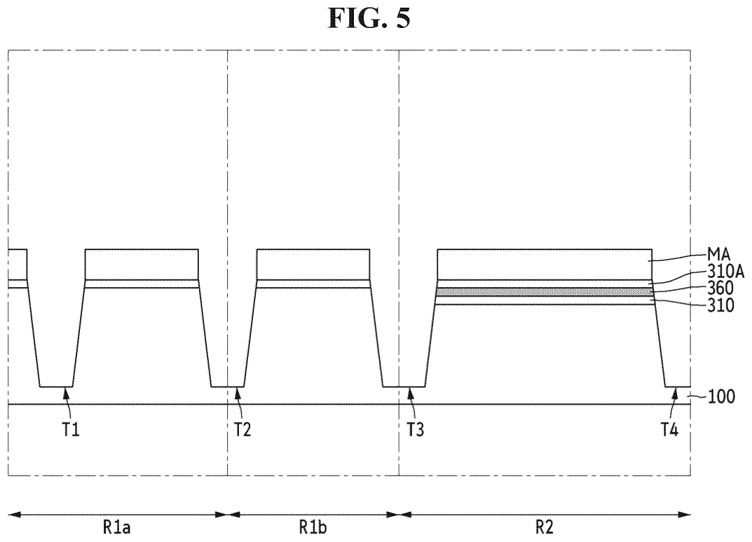

Referring to FIG. 5, a plurality of trenches T1 to T4 that partially extend into the substrate 100 may be formed in the first to third areas R1a, R1b, and R2 by using the mask pattern MA. The plurality of trenches T1 to T4 may be formed by using a photo process.

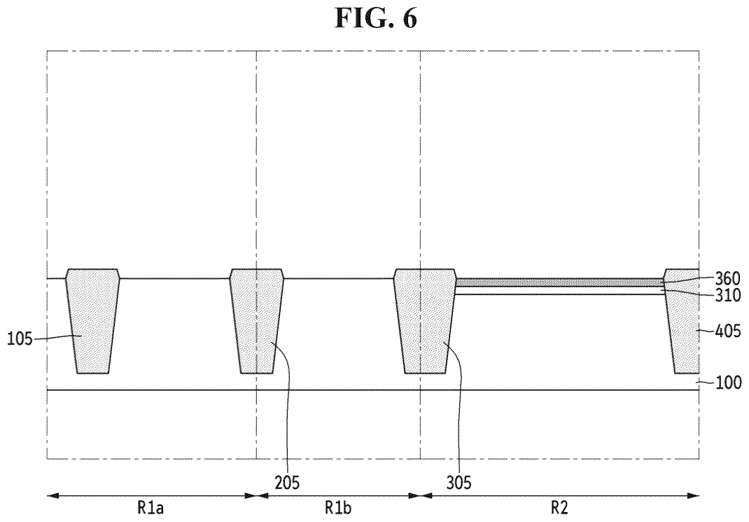

Referring to FIG. 6, each of the plurality of element isolation films 105, 205, 305, and 405 may be formed in each of the plurality of trenches T1 to T4. For example, each of the element isolation films 105, 205, 305, and 405 may include an oxide.

A planarization process may be performed on upper surfaces of the element isolation films 105, 205, 305, and 405. For example, the planarization process may be, but is not limited to, chemical mechanical polishing.

Thereafter, the oxide film 310A and the mask pattern MA may be removed.

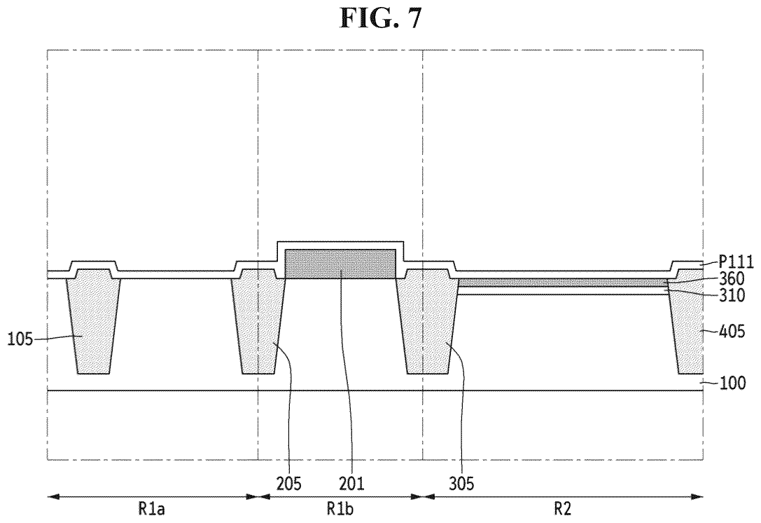

Referring to FIG. 7, the silicon germanium layer 201 may be formed on the second area R1b. The silicon germanium layer 201 may be formed between the element isolation films 205 and 305.

Afterwards, a first pre-gate dielectric film P111 may be formed on the first to third areas R1a, R1b, and R2, the plurality of element isolation films 105, 205, 305, and 405, the silicon germanium layer 201, and the first polysilicon layer 360. For example, the first pre-gate dielectric film P111 may include an oxide.

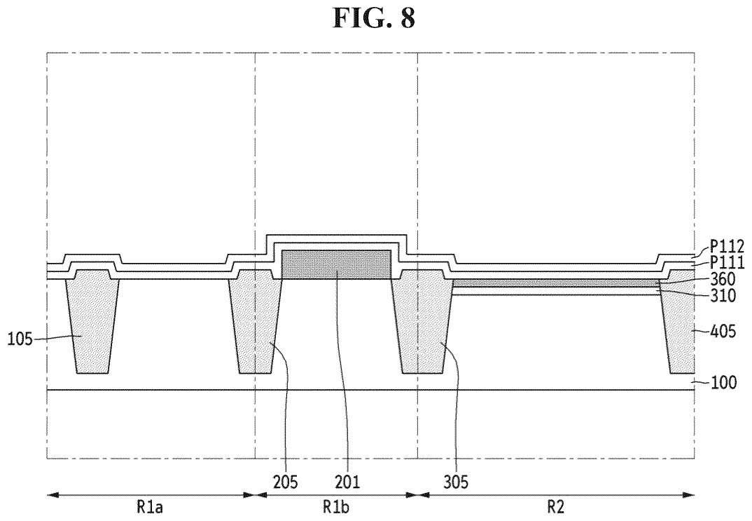

Referring to FIG. 8, a first pre-high-dielectric-constant dielectric film P112 may be formed on the first pre-gate dielectric film P111 of the first to third areas R1a, R1b, and R2. For example, the first pre-high-dielectric-constant dielectric film P112 may include hafnium oxide.

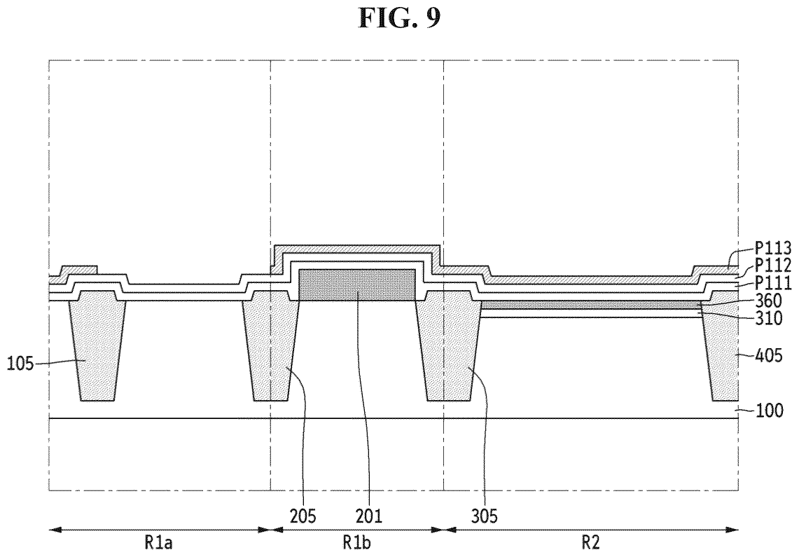

Referring to FIG. 9, a first pre-barrier film P113 may be formed on the first pre-high-dielectric constant dielectric film P112 of the first to third areas R1a, R1b, and R2. Thereafter, a portion of the first pre-barrier film P113 between the element isolation films 105 and 205 of the first area R1a may be removed. Accordingly, the first pre-barrier film P113 may be formed on the first pre-high-dielectric constant dielectric film P112 of the second and third areas R1b and R2. For example, the first pre-barrier film P113 may include titanium nitride.

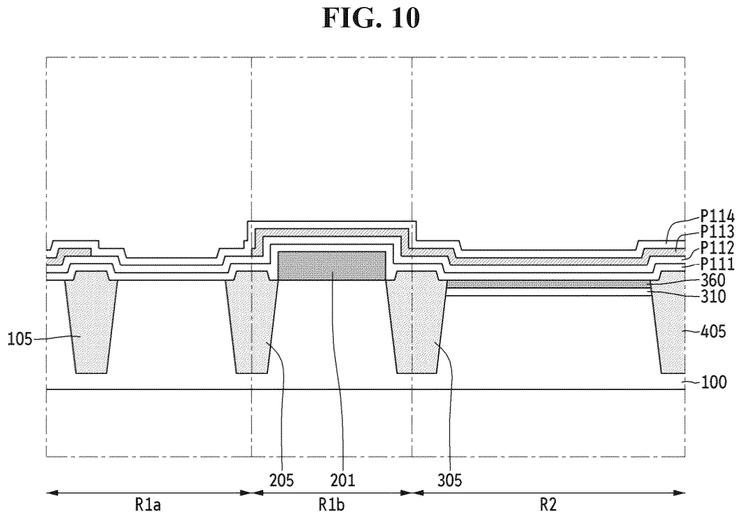

Referring to FIG. 10, a second pre-high-dielectric-constant dielectric film P114 may be formed on the first pre-barrier film P113 of the second and third areas R1b and R2 and the first pre-high-dielectric-constant dielectric film P112 of the first area R1a. For example, the second pre-high-dielectric-constant dielectric film P114 may include lanthanum oxide.

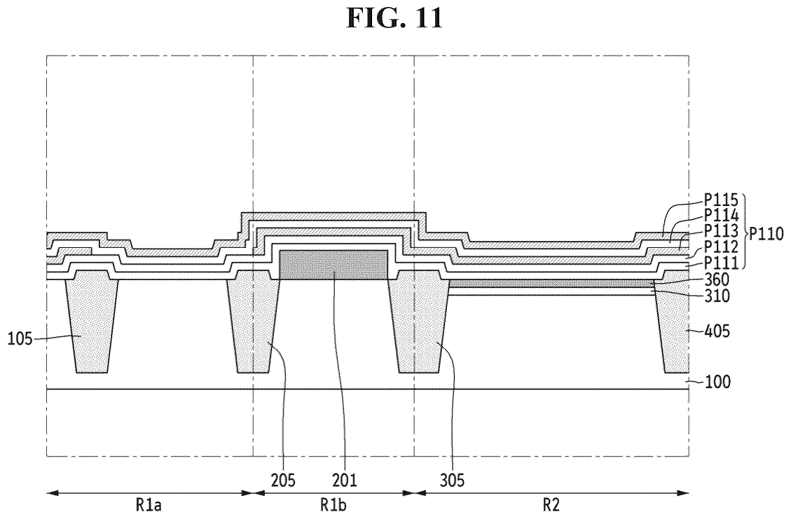

Referring to FIG. 11, a second pre-barrier film P115 may be formed on the second pre-high-dielectric-constant dielectric film P114 of the first to third areas R1a, R1b, and R2. For example, the second pre-barrier film P115 may include titanium nitride.

Accordingly, a pre-insulating structure P110 including the first pre-gate dielectric film P111, the first pre-high-dielectric constant dielectric film P112, the first pre-barrier film P113, the second pre-high-dielectric constant dielectric film P114, and the second pre-barrier film P115 may be formed on the first to third areas R1a, R1b, and R2.

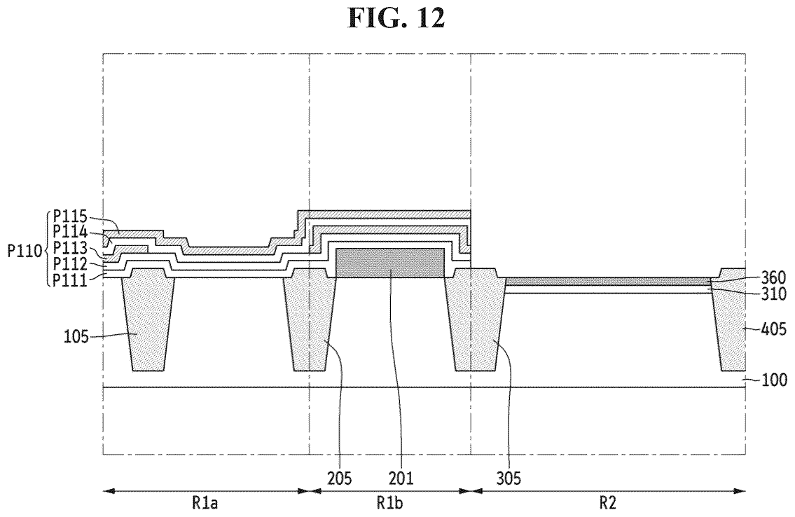

Referring to FIG. 12, a portion of the pre-insulating structure P110 that is disposed in the third area R2 may be removed to expose the element isolation films 305 and 405 and the first polysilicon layer 360 that are disposed in the third area R2.

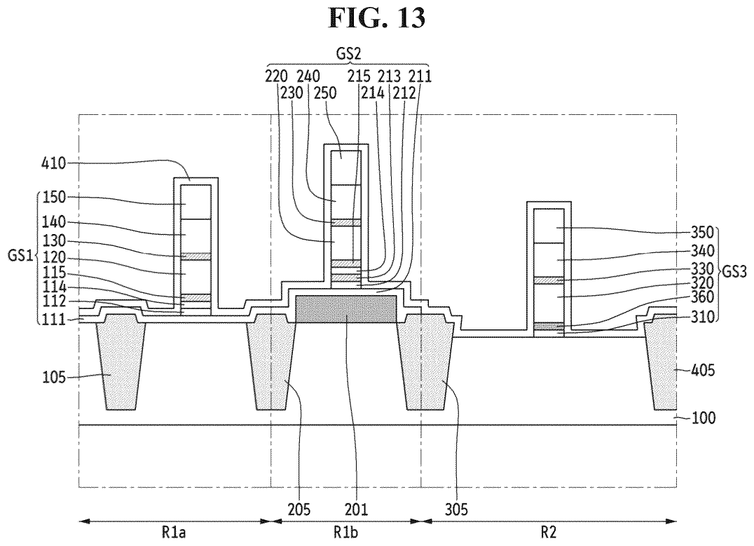

Referring to FIG. 13, the pre-insulating structure P110 in the first and second areas R1a and R1b may be patterned. Accordingly, a first gate insulating structure 111, 112, 114 and the (1-2)-nd barrier film 115 maybe formed, and a second gate insulating structure 211, 212, 214, the (2-1)-st barrier film 213 and the (2-2)-nd barrier film 215 may be formed.

Thereafter, the (1-1)-st gate electrode layer 120 may be formed on the first gate insulating structure 111, 112, 114 and the (1-2)-nd barrier film 115, and accordingly, the first gate structure GS1 may be formed. The (2-1)-st gate electrode layer 220 may be formed on the second gate insulating structure 211, 212, 214, the (2-1)-st barrier film 213 and the (2-2)-nd barrier film 215, and accordingly, the second gate structure GS2 may be formed. The (3-1)-st gate electrode layer 320 may be formed on the third gate insulating film 310, and accordingly, the third gate structure GS3 may be formed.

A vertical level of a bottom surface of a stack of the third gate insulating film 310 and the first polysilicon layer 360 may be lower than a vertical level of a bottom surface of the first gate insulating layer 110 by the first distance (D1 in FIG. 2 and FIG. 3).

According to embodiments of the present inventive concept, the polysilicon layer 360 may be formed to protect the third gate insulating film 310 prior to the trench forming process for forming the element isolation film. Accordingly, damage to the gate insulating film 310 may be prevented in the trench forming process for forming the element isolation film.

The first gate structure GS1 may be formed by sequentially stacking the first gate electrode layer 120, the first barrier film 130, the first gate electrode layer 140, and the first capping layer 150 on the (1-2)-nd barrier film 115.

The second gate structure GS2 may be formed by sequentially stacking the (2-1)-st gate electrode layer 220, the (2-3)-rd barrier film 230, the (2-2)-nd gate electrode layer 240, and the second capping layer 250 on the (2-2)-nd barrier film 215.

The third gate structure GS3 may be formed by sequentially stacking the (3-1)-st gate electrode layer 320, the (3-3)-rd barrier film 330, the (3-2)-nd gate electrode layer 340, and the third capping layer 350 on the first polysilicon layer 360.

Thereafter, the first spacer layer 410 may be formed on the upper surface and the side surface of each of the first to third gate structures GS1, GS2, and GS3. The first spacer layer 410 may be formed along the first surface R1_U and the second surface R2_U of the substrate 100.

For example, the first spacer layer 410 may include silicon nitride. For example, the first spacer layer 410 may be used to form a shallow doped layer LDD in an impurity doped area within the substrate 100.

Thereafter, the second spacer layer 420 may be formed on both opposing sidewalls of the first spacer layer 410. For example, the second spacer layer 420 may be formed on opposing side surfaces of each of the first to third gate structures GS1, GS2, and GS3 with the first spacer layer 410 disposed therebetween. For example, the second spacer layer 420 may include oxide or nitride. Accordingly, the semiconductor device as illustrated in FIG. 2 may be formed.

In one example, after forming the second spacer layer 420, a stopper nitride layer may be further formed on the substrate 100 and the gate structures GS1, GS2, and GS3. The stopper nitride layer may be used to form an interlayer insulating film on the substrate 100 and the gate structures GS1, GS2, and GS3.

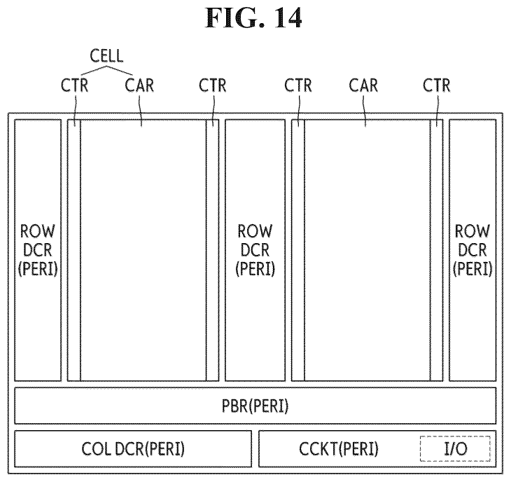

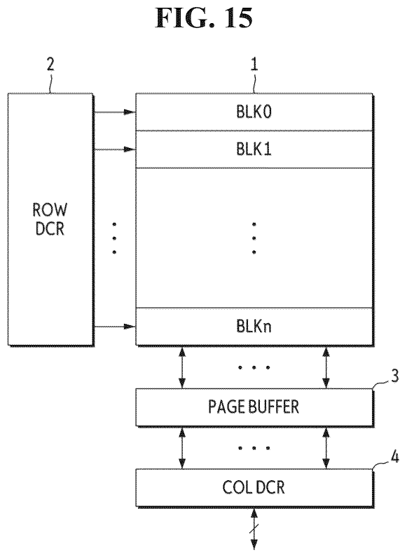

FIG. 14 is a schematic plan view for illustrating a semiconductor device according to embodiments of the present inventive concept. FIG. 15 is a block diagram for illustrating the semiconductor device of FIG. 14.

Referring to FIG. 14 and FIG. 15, a semiconductor device according to embodiments of the present inventive concept may include a cell area CELL and a peripheral circuit area PERI. The peripheral circuit area PERI may include row decoder areas ROW DCR, a page buffer area PBR, a column decoder area COL DCR and an other circuits area CCKT.

The cell area CELL may include a cell array area CAR and a contact area CTR.

A memory cell array 1 including a plurality of memory cells may be formed in the cell array area CAR. The memory cell array 1 may include a plurality of memory cells and a plurality of word-lines and a plurality of bit-lines electrically connected to the memory cells. In embodiments of the present inventive concept, the memory cell array 1 may include a plurality of memory blocks BLK0 to BLKn as data erase units.

The contact area CTR may be interposed between the cell array area CAR and the peripheral circuit area PERI. For example, the contact area CTR may be interposed between the cell array area CAR and the row decoder areas ROW DCR.

A row decoder 2 that selects the word-lines of the memory cell array 1 may be disposed in the row decoder area ROW DCR. A contact wiring structure that electrically connects the memory cell array 1 and the row decoder 2 to each other may be formed in the contact area CTR. The row decoder 2 may select one of the memory blocks BLK0 to BLKn of the memory cell array 1 based on address information and select one of the word-lines of the selected memory block. The row decoder 2 may provide a word-line voltage generated from a voltage generation circuit to each of the selected word-line and unselected word-lines, in response to control of a control circuit.

A page buffer 3 for reading information stored in the memory cells may be formed in the page buffer area PBR. Depending on an operation mode, the page buffer 3 may temporarily store therein data to be stored in the memory cells or detect data stored in the memory cells. The page buffer 3 may operate as a write driver circuit in a program operation mode and may operate as a sense amplifier circuit in a read operation mode.

A column decoder 4 connected to the bit-lines of the memory array 1 may be formed in the column decoder area COL DCR. The column decoder 4 may provide a data transmission path between the page buffer 3 and an external device (e.g., a memory controller).

The other circuits area CCKT may be disposed outside the page buffer area PBR. An input/output circuit I/O and a high-voltage generation circuit, etc. may be disposed in the other circuits area CCKT. For example, the input/output circuit I/O may be disposed at a bottom of the semiconductor device and may be connected to an external device through an I/O bus.

In embodiments of the semiconductor device, each of the areas may include high-voltage transistors and low-voltage transistors. For example, the high-voltage transistors may include transistors that generate electrical signals for the operation of memory cells, and the low-voltage transistors may include transistors that generate electrical signals for communication between the memory cells and an external host.

For example, the row decoder arca ROW DCR may include high-voltage transistors that generate program voltages, pass voltages, etc. during a program operation. The page buffer area PBR may include high-voltage transistors that generate read voltages during a read operation and erase voltages during an erase operation. In the other circuits area CCKT, the input/output circuit I/O may include low-voltage transistors that generate signals for input/output of data. In this case, the low-voltage transistors may require a high-speed operation, and thus may have a different structure from those of other transistors including the high-voltage transistors, as described above.

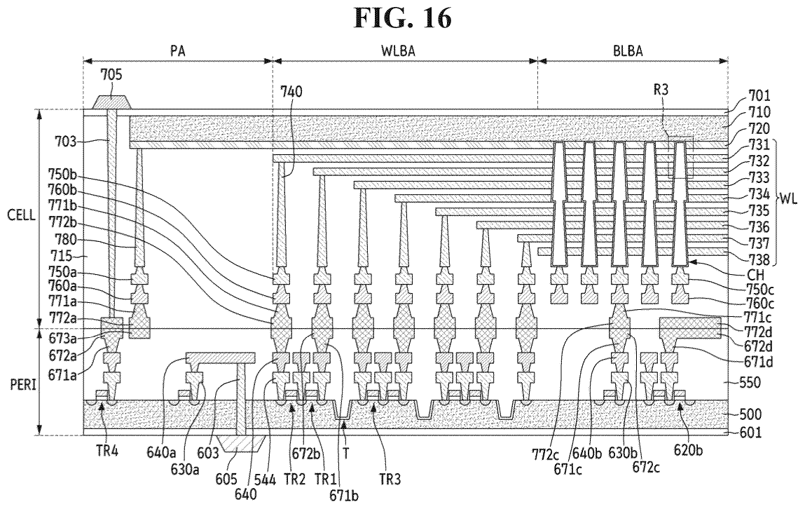

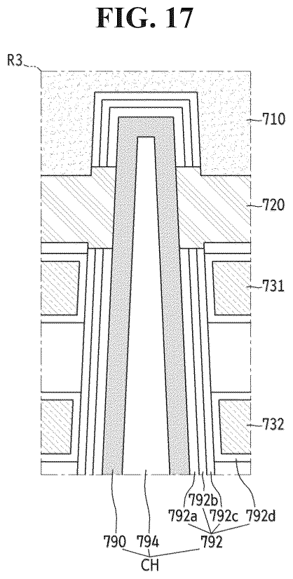

FIG. 16 is a schematic cross-sectional view illustrating a semiconductor device according to embodiments of the present inventive concept. FIG. 17 is an enlarged view of an area R3 of FIG. 16. For convenience of descriptions, contents duplicate with those described above using FIGS. 1 to 15 are briefly described or descriptions thereof are omitted.

Referring to FIG. 16, a semiconductor device according to embodiments of the present inventive concept may include a peripheral circuit area PERI and a cell area CELL.

Each of the peripheral circuit area PERI and the cell area CELL may include an external pad bonding area PA, a word-line bonding area WLBA, and a bit-line bonding arca BLBA.

The word-line bonding arca WLBA may be defined as an area where a plurality of cell contact plugs 740, etc. are disposed. A lower bonding metal 671b and 672b may be formed on a second metal layer 640 of the word-line bonding arca WLBA. In the word-line bonding area WLBA, the lower bonding metal 671b and 672b of the peripheral circuit arca PERI may be electrically connected to an upper bonding metal 771b and 772b of the cell arca CELL in a bonding manner. For example, each of the lower bonding metal 671b and 672b and the upper bonding metal 771b and 772b may include at least one of aluminum, copper, and/or tungsten. In the word-line bonding area WLBA, the cell contact plugs 740 may be connected to the peripheral circuit area PERI via the upper bonding metal 771b and 772b of the cell area CELL and the lower bonding metal 671b and 672b of the peripheral circuit arca PERI.

The bit-line bonding area BLBA may be defined as an area where a channel structure CH and a bit-line 760c are disposed. The bit-line 760c may be electrically connected to a fifth circuit element 620b in the bit-line bonding area BLBA. For example, the bit-line 760c may be connected to the upper bonding metal 771c and 772c in the peripheral circuit area PERI. The upper bonding metal 771c and 772c may be connected to the lower bonding metal 671c and 672c that is connected to the fifth circuit element 620b.

A common source line contact plug 780 may be disposed in the external pad bonding area PA. The common source line contact plug 780 may be made of a conductive material such as metal, metal compound, or polysilicon, and may be electrically connected to a common source line 720. A first metal layer 750a and a second metal layer 760a may be disposed under the common source line contact plug 780 and may be sequentially stacked. For example, an area where the common source line contact plug 780, the first metal layer 750a, and the second metal layer 760a are disposed may be defined as the external pad bonding area PA. Furthermore, input/output pads 605 and 705 may be disposed in the external pad bonding arca PA.

A metal pattern of the uppermost metal layer in each of the external pad bonding area PA and the bit-line bonding area BLBA included in the cell area CELL and peripheral circuit area PERI, may respectively exist as a dummy pattern. In addition, the uppermost metal layer in each of the external pad bonding area PA and the bit-line bonding area BLBA included in the cell area CELL and peripheral circuit area PERI, may respectively be empty.

In the semiconductor device according to embodiments of the present inventive concept, in the external pad bonding area PA, a lower metal pattern 673a of the same shape as that of an upper metal pattern 772a of the cell area CELL may be formed in the uppermost metal layer of the peripheral circuit area PERI in a corresponding manner to the upper metal pattern 772a formed in the uppermost metal layer of the cell area CELL. In an embodiment of the present inventive concept, the lower metal pattern 673a formed in the uppermost metal layer of the peripheral circuit area PERI is not be connected to a separate contact in the peripheral circuit area PERI. Similarly, in the external pad bonding area PA, an upper metal pattern of the same shape as that of a lower metal pattern of the peripheral circuit area PERI may be formed in the upper metal layer of the cell area CELL in a corresponding manner to the lower metal pattern formed in the uppermost metal layer of the peripheral circuit area PERI.

Furthermore, in the bit-line bonding area BLBA, an upper metal pattern 772d having the same shape as that of a lower metal pattern 672d of the peripheral circuit area PERI may be formed in the uppermost metal layer of the cell area CELL in a corresponding manner to the lower metal pattern 672d that is formed in the uppermost metal layer of the peripheral circuit area PERI. In an embodiment of the present inventive concept, a contact is not be formed on the upper metal pattern 772d formed in the uppermost metal layer of the cell area CELL.

The peripheral circuit area PERI may include a first substrate 500, an interlayer insulating film 550, a plurality of circuit elements TR1, TR2, TR3, TR4, and 620b formed on the first substrate 500, a first metal layer 544, 630a, and 630b connected to each of the plurality of circuit elements TR1, TR2, TR3, TR4, and 620b, and a second metal layer 640, 640a, and 640b formed on the first metal layer 544, 630a, and 630b.

The first circuit element TR4 (PT1 in FIG. 1) may be electrically connected to the second input/output pad 705. In this case, the area R1a in FIG. 1 on which the first circuit element TR4 (PT1 in FIG. 1) is disposed may correspond to the other circuits area CCKT of FIG. 14.

The second circuit element TR4 (PT2 in FIG. 1) may be electrically connected to the second input/output pad 705. In this case, the second area R1b in FIG. 1 on which the second circuit element TR4 (PT2 in FIG. 1) is disposed may correspond to the other circuits area CCKT of FIG. 14.

The third circuit element PT3 in FIG. 1 may be any one of the plurality of circuit elements TR1, TR2, and TR3.

The third circuit element PT3 in FIG. 1 may be electrically connected to a word line WL. In this case, the third area R2 in FIG. 1 on which the third circuit element PT3 in FIG. 1 is disposed may correspond to the row decoder area ROW DCR of FIG. 14.

In addition, the third circuit element PT3 in FIG. 1 may be electrically connected to a bit line BL. In this case, the area R2 in FIG. 1 on which the third circuit element PT3 of FIG. 1 is disposed may correspond to the page buffer area PBR of FIG. 14.

A trench T may be the trench T4 illustrated in FIGS. 3 to 13.

Herein, only the first metal layer 544, 630a, and 630b and the second metal layer 640, 640a, and 640b are illustrated and described. However, the present inventive concept is not limited thereto, and at least one or more metal layers may be formed on the second metal layer 640, 640a, and 640b. At least some of the one or more metal layers formed on the second metal layer 640, 640a, and 640b may be made of aluminum or the like having a lower resistance than that of copper constituting the second metal layer 640, 640a, and 640b.

In embodiments of the present inventive concept, the first metal layer 544, 630a, and 630b may be made of relatively high resistivity tungsten, and the second metal layer 640, 640a, and 640b may be made of relatively low resistivity copper.

An interlayer insulating film 550 may be disposed on the first substrate 500 to cover the plurality of circuit elements TR1, TR2, TR3, TR4, and 620b, the first metal layer 544, 630a, and 630b, and the second metal layer 640, 640a, and 640b.

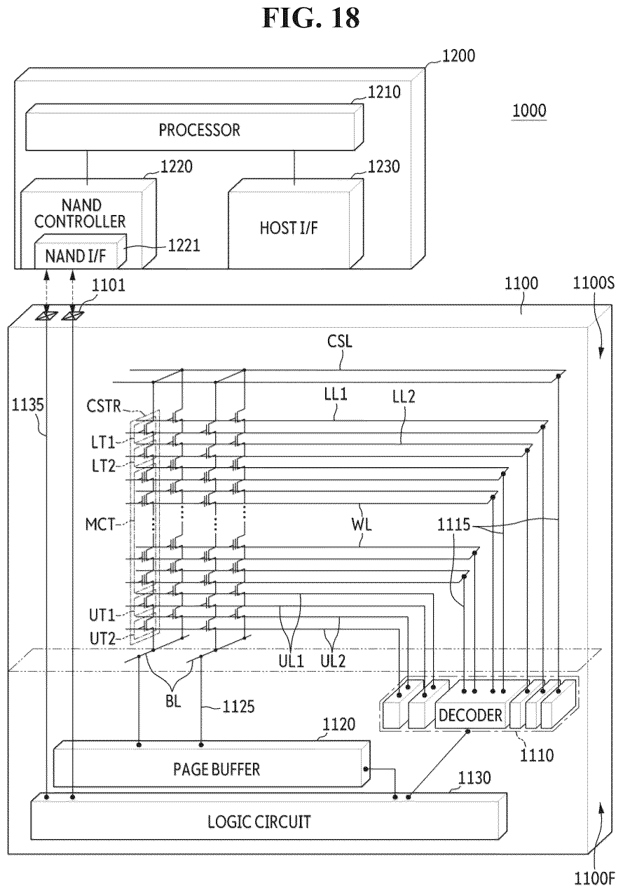

The cell area CELL may provide at least one memory block. The cell area CELL may include a second substrate 710 and a common source line 720. On the second substrate 710, a plurality of word lines 731 to 738 (WL) may be stacked along a vertical direction intersecting an upper surface of the second substrate 710. A string select line (for example, UL1 and UL2 of FIG. 18), and a ground select line (for example, LL1 and LL2 of FIG. 18) may be respectively disposed on top of and under a stack of the word lines WL, and the plurality of word lines WL may be disposed between the string select lines and the ground select lines.

A channel structure CH may extend in the vertical direction and extend through the word lines WL, the string select lines, and the ground select lines. As illustrated in FIG. 17, the channel structure CH may include a semiconductor pattern 790 and an information storage film 792.

The semiconductor pattern 790 may extend in a vertical direction. Although the semiconductor pattern 790 is illustrated as having a cup shape, this is merely an example, and the semiconductor pattern 790 may have various shapes such as a cylindrical shape, a square cylinder shape, and a solid pillar shape. The semiconductor pattern 790 may include, but is not limited to, a semiconductor material such as single crystal silicon, polycrystalline silicon, an organic semiconductor, and carbon nanostructures.

The information storage film 792 may be interposed between the semiconductor pattern 790 and the word lines WL. For example, the information storage film 792 may extend along a side surface of the semiconductor pattern 790.

In embodiments of the present inventive concept, the information storage film 792 may be formed as a stack of multi films. For example, the information storage film 792 may include a tunnel insulating film 792a, a charge storage film 792b, and a blocking insulating film 792c that are sequentially stacked on the semiconductor pattern 790. The tunnel insulating film 792a may include, for example, silicon oxide or a high dielectric constant material having a dielectric constant that is higher than that of silicon oxide, for example, aluminum oxide (Al₂O₃), hafnium oxide (HfO₂). The charge storage film 792b may include, for example, silicon nitride. The blocking insulating film 792c may include, for example, silicon oxide or a high dielectric constant material having a dielectric constant that is higher than that of silicon oxide. In embodiments of the present inventive concept, the information storage film 792 may further include a gate insulating film 792d extending along a surface of each word line WL. For example, the gate insulating film 792d may be disposed on the blocking insulating film 792c.

In embodiments of the present inventive concept, the channel structure CH may further include a filling pattern 794. The filling pattern 794 may be formed to fill an inner space of the semiconductor pattern 790. For example, the inner space of the semiconductor pattern 790 may have a cylindrical shape. The filling pattern 794 may include, but is not limited to, an insulating material, for example, silicon oxide.

The common source line 720 may be formed to contact the semiconductor pattern 790 of the channel structure CH.

As illustrated in FIG. 17, in embodiments of the present inventive concept, the channel structure CH may extend through the common source line 720 to be partially embedded within the second substrate 710. The common source line 720 may extend through a portion of the information storage film 792 to contact a side surface of the semiconductor pattern 790.

In some embodiments of the present inventive concept, at least a portion of the common source line 720 may be embedded within the second substrate 710. The common source line 720 may be formed, for example, in a Selective Epitaxial Growth (SEG) process from the second substrate 710. The channel structure CH may extend through a portion of the information storage film 792 to contact an upper surface of the common source line 720.

The channel structure CH may be electrically connected to a first metal layer 750c and a second metal layer 760c. For example, the first metal layer 750c may be a bit line contact, and the second metal layer 760c may be the bit line BL of FIG. 18. In embodiments of the present inventive concept, the bit line 760c may extend along the second direction parallel to an upper surface of the second substrate 710.

The word-lines WL may extend along a direction (e.g., the first direction) parallel to the upper surface of the second substrate 710, and may be connected to a plurality of cell contact plugs 740. The word-lines WL and the cell contact plugs 740 may be connected to each other via pads formed by extending at least some of the word-lines WL by different lengths. For example, the word-lines WL may be stacked on each other such that they form a stair-case structure. A first metal layer 750b and a second metal layer 760b may be sequentially stacked and may be disposed under each of the cell contact plugs 740 that are connected to the word-lines WL. The first metal layer 750b and the second metal layer 760b may be connected to a bottom of each of the cell contact plugs 740 that are connected to the word-lines WL.

In embodiments of the present inventive concept, a lower insulating film 601 covering a lower surface of the first substrate 500 may be formed under the first substrate 500, and a first input/output pad 605 may be formed on the lower insulating film 601. The first input/output pad 605 may be connected to at least one of the plurality of circuit elements TR1, TR2, TR3, TR4, and 620b, which are disposed in the peripheral circuit area PERI, via a first input/output contact plug 603 and may be insulated from the first substrate 500 via a lower insulating film 601. Furthermore, a side insulating film may be disposed between the first input/output contact plug 603 and the first substrate 500 to electrically insulate the first input/output contact plug 603 from the first substrate 500.

In embodiments of the present inventive concept, an upper insulating film 701 covering the upper surface of the second substrate 710 may be formed on top of the second substrate 710, and a second input/output pad 705 may be disposed on the upper insulating film 701. The second input/output pad 705 may be connected to at least one of the plurality of circuit elements TR1, TR2, TR3, TR4, and 620b disposed in the peripheral circuit area PERI via a second input/output contact plug 703.

In embodiments of the present inventive concept, the second substrate 710 and the common source line 720 might not be disposed in an area where the second input/output contact plug 703 is disposed. Furthermore, the second input/output pad 705 might not overlap the word-lines WL in the vertical direction. The second input/output contact plug 703 may be insulated from the second substrate 710 in a direction (e.g., the first direction X) parallel to the upper surface of the second substrate 710 and may extend through the interlayer insulating film 315 in the cell area CELL to be connected to the second input/output pad 705.

In embodiments of the present inventive concept, the first input/output pad 605 and the second input/output pad 705 may be optionally formed. For example, the semiconductor device according to some embodiments of the present inventive concept may include only the first input/output pad 605 disposed on the first substrate 500, or may include only the second input/output pad 705 disposed on the second substrate 710. In addition, the semiconductor device according to some embodiments of the present inventive concept may include both the first input/output pad 605 and the second input/output pad 705.

FIG. 18 is an example block diagram for illustrating an electronic system according to embodiments of the present inventive concept.

Referring to FIG. 18, an electronic system 1000 according to embodiments of the present inventive concept may include a semiconductor device 1100 and a controller 1200 electrically connected to the semiconductor device 1100. The electronic system 1000 may be a storage device including one or a plurality of semiconductor devices 1100 or may be an electronic device including the storage device. For example, the electronic system 1000 may be a solid state drive (SSD) device, a universal serial bus (USB) device, a computing system, a medical device, or a communication device including one or a plurality of semiconductor devices 1100.

The semiconductor device 1100 may be a non-volatile memory device, for example, a NAND flash memory device as described above with reference to FIGS. 1 to 17. The semiconductor device 1100 may include a first structure 1100F and a second structure 1100S disposed on the first structure 1100F. In embodiments of the present inventive concept, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit-line BL, common source line CSL, word-lines WL, first and second gate upper lines UL1 and UL2, first and second gate lower lines LL1 and LL2, and memory cell strings CSTR between the bit-line BL and the common source line CSL.

In the second structure 1100S, each memory cell string CSTR may include lower transistors LT1 and LT2, which are adjacent to the common source line CSL, upper transistors UT1 and UT2, which are adjacent to the bit-line BL, and a plurality of memory cell transistors MCT that are disposed between the lower transistors LT1 and LT2 and the upper transistors UT1 and UT2. The number of lower transistors LT1 and LT2 and the number of upper transistors UT1 and UT2 may vary.

In embodiments of the present inventive concept, the upper transistors UT1 and UT2 may include a string select transistor, and the lower transistors LT1 and LT2 may include a ground select transistor. The gate lower lines LL1 and LL2 may be gate electrodes of the lower transistors LT1 and LT2, respectively. The word-lines WL may be gate electrodes of the memory cell transistors MCT, respectively. The gate upper lines UL1 and UL2 may be gate electrodes of the upper transistors UT1 and UT2, respectively.

The common source line CSL, the first and second gate lower lines LL1 and LL2, the word-lines WL, and the first and second gate upper lines UL1 and UL2 may be electrically connected to the decoder circuit 1110 via first connection wirings 1115 extending in the first structure 1100F to the second structure 1100S. The bit-lines BL may be electrically connected to the page buffer 1120 via second connection wirings 1125 extending in the first structure 1100F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1000 may communicate with a controller 1200 via an input/output pad 1101 that is electrically connected to the logic circuit 1130. The input/output pad 1101 may be electrically connected to the logic circuit 1130 via an input/output connection wiring 1135 extending in the first structure 1100F to the second structure 1100S.

The controller 1200 may include a processor 1210, a NAND controller 1220, and a host interface 1230. According to embodiments of the present inventive concept, the electronic system 1000 may include a plurality of semiconductor devices 1100. In this case, the controller 1200 may control the plurality of semiconductor devices 1100.

The processor 1210 may control overall operations of the electronic system 1000 including the controller 1200. The processor 1210 may operate based on predefined firmware, and may control the NAND controller 1220 to access the semiconductor device 1100. The NAND controller 1220 may include a NAND interface 1221 that processes communication with the semiconductor device 1100. Via the NAND interface 1221, a control command for controlling the semiconductor device 1100, data to be written to memory cell transistors MCT of the semiconductor device 1100, and data to be read from the memory cell transistors MCT of the semiconductor device 1100 may be transmitted. The host interface 1230 may provide a communication function between the electronic system 1000 and an external host. Upon receiving a control command from an external host via the host interface 1230, the processor 1210 may control the semiconductor device 1100 in response to the control command.

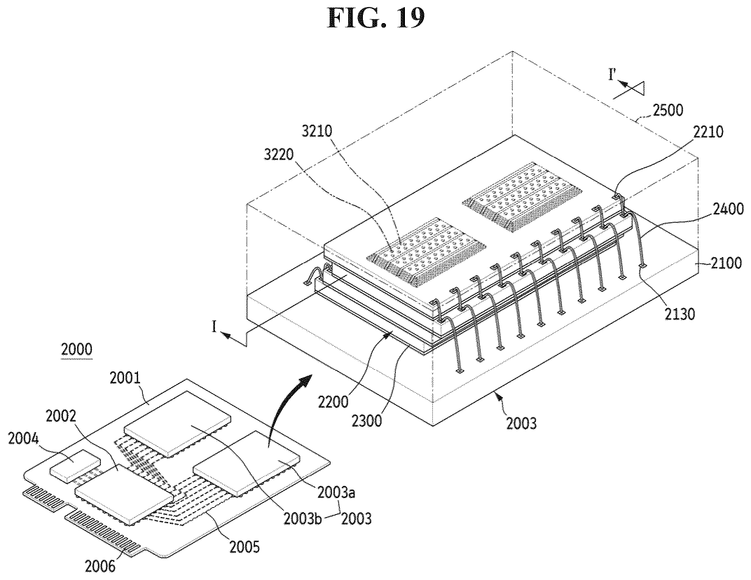

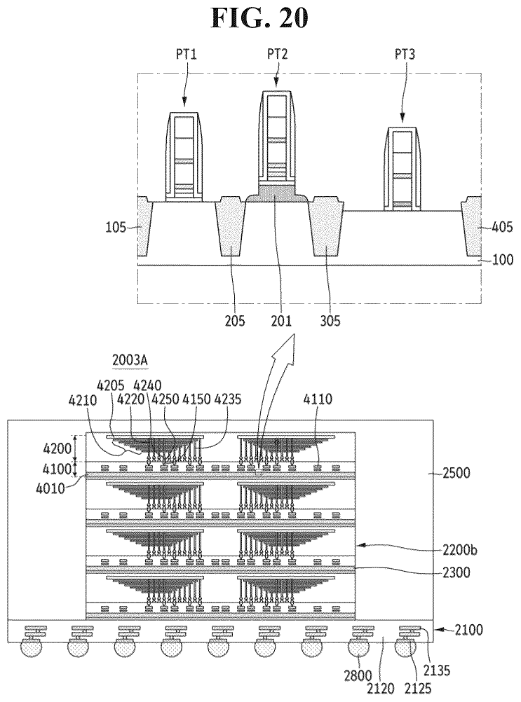

FIG. 19 is an example perspective view for illustrating an electronic system according to embodiments of the present inventive concept. FIG. 20 shows a schematic cross-sectional view cut along a line I-I′ in FIG. 19. For convenience of descriptions, contents duplicate with those described above using FIGS. 1 to 18 are briefly described or descriptions thereof are omitted.

Referring to FIG. 19, an electronic system 2000 according to embodiments of the present inventive concept may include a main substrate 2001, a main controller 2002 mounted on the main substrate 2001, at least one semiconductor package 2003, and at least one DRAM 2004. The semiconductor package 2003 and he DRAM 2004 may be connected to the main controller 2002 via line patterns 2005 that are formed on the main substrate 2001.

The main substrate 2001 may include a connector 2006 including a plurality of pins that are coupled to an external host. The number and an arrangement of the plurality of pins in the connector 2006 may vary based on a communication interface between the electronic system 2000 and the external host. In embodiments of the present inventive concept, the electronic system 2000 may communicate with the external host using one of interfaces such as USB (Universal Serial Bus), PCI-Express (Peripheral Component Interconnect Express), SATA (Serial Advanced Technology Attachment), M-Phy for UFS (Universal Flash Storage), etc. In embodiments of the present inventive concept, the electronic system 2000 may operate using power supplied from the external host via the connector 2006. The electronic system 2000 may further include a power management integrated circuit (PMIC) for distributing power supplied from the external host to the main controller 2002 and the semiconductor package 2003.

The main controller 2002 may write data to the semiconductor package 2003 or read data from the semiconductor package 2003, and may increase an operating speed of the electronic system 2000.

The DRAM 2004 may act as a buffer memory for reducing a difference between operation speeds of the semiconductor package 2003, which is functioning as a data storage space, and the external host. The DRAM 2004 included in electronic system 2000 may operate as a cache memory, and may provide a space for temporarily storing data therein in a control operation of the semiconductor package 2003. When the DRAM 2004 is included in the electronic system 2000, the main controller 2002 may further include a DRAM controller for controlling the DRAM 2004 in addition to a NAND controller for controlling the semiconductor package 2003.

The semiconductor package 2003 may include a first semiconductor package 2003a and a second semiconductor package 2003b spaced apart from each other. Each of the first semiconductor package 2003a and the second semiconductor package 2003b may be embodied as a semiconductor package including a plurality of semiconductor chips 2200. Each of the first semiconductor package 2003a and the second semiconductor package 2003b may include a package substrate 2100, semiconductor chips 2200 on the package substrate 2100, adhesive layers 2300 disposed on a bottom face of each of the semiconductor chips 2200, a connection structure 2400 electrically connecting the semiconductor chips 2200 and the package substrate 2100 to each other, and a molding layer 2500 disposed the package substrate 2100 and covering the semiconductor chips 2200 and the connection structure 2400.

The package substrate 2100 may be embodied as a printed circuit board including package upper pads 2130. Each semiconductor chip 2200 may include an input/output pad 2210. The input/output pad 2210 may correspond to the input/output pad 1101 in FIG. 18. Each of the semiconductor chips 2200 may include memory blocks 3210 and channel structures 3220. The memory block 3210 may correspond to the memory block in FIG. 16, and the channel structure 3220 may correspond to the channel structure CH in FIG. 16.

In embodiments of the present inventive concept, the connection structure 2400 may be embodied as a bonding wire that electrically connects the input/output pad 2210 and the package upper pads 2130 to each other. Accordingly, in each of the first semiconductor package 2003a and the second semiconductor package 2003b, the semiconductor chips 2200 may be electrically connected to each other in a bonding wire scheme, and may be electrically connected to the package upper pads 2130 of the package substrate 2100. In embodiments of the present inventive concept, in each of the first semiconductor package 2003a and the second semiconductor package 2003b, the semiconductor chips 2200 may be electrically connected to each other via a connection structure including a through electrode (Through Silicon Via: TSV) instead of the connection structure 2400 using the bonding wire scheme.

In embodiments of the present inventive concept, the main controller 2002 and the semiconductor chips 2200 may be included in one package. In embodiments of the present inventive concept, the main controller 2002 and the semiconductor chips 2200 may be mounted on a separate interposer substrate that is different from the main substrate 2001, and the main controller 2002 and the semiconductor chips 2200 may be connected to each other via a wiring that is formed in the interposer substrate.

Referring to FIG. 20, in the semiconductor package 2003A, the package substrate 2100 may be a printed circuit substrate. The package substrate 2100 may include a package substrate body 2120, package upper pads 2130 of FIG. 19 disposed on a first surface (e.g., an upper surface) of the package substrate body 2120, lower pads 2125 disposed on a second surface (e.g., a lower surface) of the package substrate body 2120 or exposed through the second surface of the package substrate body 2120, and internal wirings 2135 electrically connecting the upper pads 2130 and the lower pads 2125 to each other while being disposed within the package substrate body 2120. The upper pads 2130 may be electrically connected to the connection structures 2400. The lower pads 2125 may be connected to the wiring patterns 2005 of the main substrate 2001 of the electronic system 2000 as shown in FIG. 19 via conductive connectors 2800.

Each of the semiconductor chips 2200 may include a semiconductor substrate 4010, a first structure 4100 on the semiconductor substrate 4010, and a second structure 4200 disposed on the first structure 4100 and bonded to the first structure 4100 in a wafer bonding manner.

The first structure 4100 may include a peripheral circuit area including peripheral wiring 4110 and first bond structures 4150. The second structure 4200 may include a common source line 4205, a gate stack structure 4210 between the common source line 4205 and the first structure 4100, memory channel structures 4220 extending through the gate stack structure 4210, and second bond structures 4250 electrically connected to the memory channel structures 4220 and the word-lines (WL in FIG. 18) of the gate stack structure 4210, respectively. For example, the second bond structures 4250 may be electrically connected to the memory channel structures 4220 and the word-lines (WL in FIG. 18), respectively, via the bit-lines 4240, which are electrically connected to the memory channel structures 4220, and gate connection wirings 4235, which are electrically connected to the word-lines (WL in FIG. 18). The first bond structures 4150 of the first structure 4100 and the second bond structures 4250 of the second structure 4200 may be bonded to each other while contacting each other. A bonded portion of each of the first bond structures 4150 and the second bond structures 4250 may be made of, for example, copper (Cu).

Each of the semiconductor chips 2200 may further include an input/output pad (2210 in FIG. 19) that is electrically connected to the peripheral wirings 4110 of the first structure 4100.

The semiconductor substrate 4010 may correspond to the first substrate 500 of FIG. 16. The first structure 4100 may correspond to the peripheral circuit area PERI of FIG. 16, and the second structure 4200 may correspond to the cell area CELL of FIG. 16.

The first structure 4100 may include the semiconductor device as described using FIG. 1 and FIG. 2. For example, the first structure 4100 may include the substrate 100, the first peripheral transistor PT1, the second peripheral transistor PT2, and the third peripheral transistor PT3.

The first peripheral transistor PT1 may include the first gate insulating film 110 of FIG. 2, which includes a material having a dielectric constant that is higher than that of silicon oxide, and the first gate electrode layer GE1 of FIG. 2, which is disposed on the first gate insulating film 110 of FIG. 2.

The second peripheral transistor PT2 may include the second gate insulating film 210 of FIG. 2, which includes a material having a dielectric constant that is higher than that of silicon oxide, and the second gate electrode layer GE2 of FIG. 2, which is disposed on the second gate insulating film 210 of FIG. 2.

The third peripheral transistor PT3 may include the third gate insulating film 310 of FIG. 2, which includes a material having a dielectric constant that is different from that of each of the first and second gate insulating films 110 and 210 of FIG. 2, the first polysilicon layer 360 of FIG. 2, which is disposed on the third gate insulating film 310 of FIG. 2, and the second polysilicon layer 320 of FIG. 2, which is disposed on the first polysilicon layer 360 of FIG. 2.

The substrate 100 may have an upper surface of a first vertical level in an area where the first peripheral transistor PT1 and the second peripheral transistor PT2 are disposed, and the substrate 100 may also have an upper surface of a second vertical level in an area where the third peripheral transistor PT3 is disposed. The first vertical level and the second vertical level may be different from each other.

A vertical level of the first polysilicon layer 360 may be positioned between the first vertical level and the second vertical level, and the second polysilicon layer 320 may be positioned at the first vertical level.

The carbon contents of the first polysilicon layer 360 of FIG. 2 and the second polysilicon layer 320 of FIG. 2 may be different from each other.

The first gate electrode layer GE1 of FIG. 2 and the third gate electrode layer GE3 of FIG. 2 may be positioned at different vertical levels from each other, and the second gate electrode layer GE2 of FIG. 2 and the third gate electrode layer GE3 of FIG. 2 may be positioned at different vertical levels from each other. The distance between the first gate electrode layer GE1 of FIG. 2 and the third gate electrode layer GE3 of FIG. 2 may be smaller than the distance between the second gate electrode layer GE2 of FIG. 2 and the third gate electrode layer GE3 of FIG. 2.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor device comprising:
a substrate including a first area and a second area, wherein the first area has a first surface, and the second area has a second surface, wherein a vertical level of the first surface is different from a vertical level of the second surface;
a first gate structure disposed on the first surface of the first area, wherein the first gate structure includes a first gate insulating film and a first gate electrode layer that is disposed on the first gate insulating film;
a second gate structure disposed on the second surface of the second area, wherein the second gate structure includes a second gate insulating film and a second gate electrode layer, wherein the second gate insulating film includes a material having a dielectric constant that is lower than a dielectric constant of the first gate insulating film, and the second gate electrode layer is disposed on the second gate insulating film; and
an element isolation film disposed in the substrate and between the first and second gate structures,
wherein the second gate electrode layer includes first and second polysilicon layers sequentially stacked on the second gate insulating film and including different materials from each other,
wherein the first polysilicon layer is disposed between the first surface and the second surface, and the second polysilicon layer is disposed at a vertical level that is above the vertical level of the first surface.

2. The semiconductor device of claim 1, wherein in a direction perpendicular to the first surface and the second surface, the vertical level of the second surface is lower than the vertical level of the first surface.

3. The semiconductor device of claim 1, wherein a distance between the first surface and the second surface is equal to a sum of a thickness of the second gate insulating film and a thickness of the first polysilicon layer.

4. The semiconductor device of claim 1, wherein a distance between the first surface and the second surface is equal to a distance between an upper surface of the first polysilicon layer and the second surface.

5. The semiconductor device of claim 1, wherein in a direction perpendicular to the first surface and the second surface, a vertical level of the second gate insulating film is lower than a vertical level of the first gate insulating film.

6. The semiconductor device of claim 1, wherein in a direction perpendicular to the first surface and the second surface, a vertical level of the first polysilicon layer is lower than a vertical level of the first gate insulating film.

7. The semiconductor device of claim 1, wherein in a direction perpendicular to the first surface and the second surface, a vertical level of the second gate structure is lower than a vertical level of the first gate structure.

8. The semiconductor device of claim 1, wherein the first gate structure is positioned on a silicon germanium layer that is disposed between the first gate insulating film and the first surface.

9. The semiconductor device of claim 8, wherein the first gate insulating film includes a first gate dielectric film, a first high dielectric constant dielectric film, a first barrier film, a second high dielectric constant dielectric film, and a second barrier film that are sequentially stacked on the silicon germanium layer,
wherein the first gate electrode layer includes a first electrode layer, a third barrier film, a second electrode layer, and a capping layer that are sequentially stacked on the second barrier film.

10. The semiconductor device of claim 1, wherein the first gate insulating film includes a first gate dielectric film, a first high dielectric constant dielectric film, a second high dielectric constant dielectric film, and a second barrier film sequentially stacked on the first surface,
wherein the first gate electrode layer includes a first electrode layer, a third barrier film, a second electrode layer, and a capping layer that are sequentially stacked on the second barrier film.

11. The semiconductor device of claim 1, wherein a carbon content of the first polysilicon layer is different from a carbon content of the second polysilicon layer.

12. A semiconductor device comprising:
a cell area; and
a peripheral circuit area electrically connected to the cell area,
wherein the cell area includes:
a plurality of gate electrodes stacked and spaced apart from each other in a first direction; and
a channel structure extending through the plurality of gate electrodes in the first direction,
wherein the peripheral circuit area includes:
a substrate including different first to third areas;
a first peripheral transistor disposed on the first area and including a first gate insulating film and a first gate electrode layer, wherein the first gate insulating film includes a material having a dielectric constant that is higher than a dielectric constant of silicon oxide, and the first gate electrode layer is disposed on the first gate insulating film;
a second peripheral transistor disposed on the second area and including a second gate insulating film and a second gate electrode layer, wherein the second gate insulating film includes a material having a dielectric constant that is higher than a dielectric constant of silicon oxide, and the second gate electrode layer is disposed on the second gate insulating film; and
a third peripheral transistor disposed on the third area and including a third gate insulating film, a first polysilicon layer, and a second polysilicon layer, wherein the third gate insulating film includes a material having a dielectric constant that is different from a dielectric constant of each of the first and second gate insulating films, wherein the first polysilicon layer is disposed on the third gate insulating film, and the second polysilicon layer is disposed on the first polysilicon layer,
wherein a carbon content of the first polysilicon layer and a carbon content of the second polysilicon layer are different from each other,
wherein the first peripheral transistor and the third peripheral transistor are positioned at different vertical levels from each other, and the second peripheral transistor and the third peripheral transistor are positioned at different vertical levels from each other,
wherein a first distance in the vertical direction between the first peripheral transistor and the third peripheral transistor is smaller than a second distance in the vertical direction between the second peripheral transistor and the third peripheral transistor.

13. The semiconductor device of claim 12, wherein the first gate insulating film, the second gate insulating film, and the third gate insulating film are not positioned at a same vertical level.

14. The semiconductor device of claim 12, wherein the first gate insulating film includes a (1-1)-st gate dielectric film, a (1-1)-st high dielectric constant dielectric film, a (1-2)-nd high dielectric constant dielectric film, and a (1-2)-nd barrier film that are sequentially stacked on the substrate,
wherein the first gate electrode layer includes a (1-1)-st gate electrode layer, a (1-3)-rd barrier film, a (1-2)-nd gate electrode layer, and a first capping layer that are sequentially stacked on the (1-2)-nd barrier film.

15. The semiconductor device of claim 12, wherein the second gate insulating film is disposed on a silicon germanium layer,
wherein the second gate insulating film includes a (2-1)-st gate dielectric film, a (2-1)-st high dielectric constant dielectric film, a (2-1)-st barrier film, a (2-2)-nd high dielectric constant dielectric film, and a (2-2)-nd barrier film that are sequentially stacked on the silicon germanium layer,
wherein the second gate electrode layer includes a (2-1)-st gate electrode layer, a (2-3)-rd barrier film, a (2-2)-nd gate electrode layer, and a second capping layer that are sequentially stacked on the (2-2)-nd barrier film.

16. The semiconductor device of claim 12, wherein the first peripheral transistor is an NMOS transistor, and the second peripheral transistor is a PMOS transistor.

17. The semiconductor device of claim 12, wherein each of the first and second peripheral transistor is a low-voltage transistor,
wherein the third peripheral transistor is a high-voltage transistor.

18. An electronic system comprising:
a main substrate;
a semiconductor device disposed on the main substrate and including a cell area and a peripheral circuit area; and
a controller disposed on the main substrate and electrically connected to the semiconductor device,
wherein the semiconductor device includes:
a first substrate disposed on the cell area;
a plurality of word lines stacked on the first substrate and spaced apart from each other;
a channel structure extending in a vertical direction intersecting with an upper surface of the first substrate to extend through the plurality of word lines;
a bit line disposed on the plurality of word lines and connected to the channel structure;
a second substrate disposed on the peripheral circuit area and including different first to third areas; and
a peripheral circuit element disposed on the second substrate,
wherein the peripheral circuit element includes:
a first peripheral transistor disposed on the first area and including a first gate insulating film, which includes a material having a dielectric constant that is higher than a dielectric constant of silicon oxide, and a first gate electrode layer, which is disposed on the first gate insulating film;
a second peripheral transistor disposed on the second area and including a second gate insulating film, which includes a material having a dielectric constant that is higher than a dielectric constant of silicon oxide, and a second gate electrode layer, which is disposed on the second gate insulating film; and
a third peripheral transistor disposed on the third area and including a third gate insulating film, which includes a material having a dielectric constant that is different from a dielectric constant of each of the first and second gate insulating films, a first polysilicon layer, which is disposed on the third gate insulating film, and a second polysilicon layer, which is disposed on the first polysilicon layer,
wherein the first polysilicon layer and the second polysilicon layer include different materials from each other,
wherein the second substrate has a first upper surface, which has a first vertical level in the first and second areas, and a second upper surface, which has a second vertical level in the third area, wherein the first vertical level and the second vertical level are different from each other,
wherein a vertical level of the first polysilicon layer is positioned between the first vertical level and the second vertical level, and the second polysilicon layer is positioned at the first vertical level.

19. The electronic system of claim 18, wherein a first difference between a vertical level of the first peripheral transistor and a vertical level of the third peripheral transistor is smaller than a second difference between a vertical level of the second peripheral transistor and the vertical level of the third peripheral transistor.

20. The electronic system of claim 18, wherein a carbon content of the first polysilicon layer is different from a carbon content of the second polysilicon layer.
